(19) United States
(12) Patent Application Publication
(10) Pub. No.: US 2024/0324434 A1
(43) Pub. Date: Sep. 26, 2024

(54) APPARATUS AND METHOD FOR MANUFACTURING DISPLAY DEVICE

(71) Applicant: Samsung Display Co., Ltd., Yongin-si (KR)

(72) Inventors: Jeongkuk Kim, Yongin-si (KR); Duckjung Lee, Yongin-si (KR); Sugwoo Jung, Yongin-si (KR)

(73) Assignee: Samsung Display Co., Ltd., Yongin-si (KR)

(21) Appl. No.: 18/526,132

(22) Filed: Dec. 1, 2023

(30) Foreign Application Priority Data
Mar. 24, 2023 (KR) 10-2023-0039061
Jun. 22, 2023 (KR) 10-2023-0080675

(51) Int. Cl. H10K 71/16; C23C 14/04

(52) U.S. Cl. CPC H10K 71/166; C23C 14/042

(57) ABSTRACT

An apparatus for manufacturing a display device includes a mask assembly arranged in the chamber and facing a display substrate, a magnetic force portion arranged in the chamber and applying a magnetic force to the mask assembly, and a deposition source. The mask assembly includes a first mask layer having a first mask opening formed therein and a second mask layer disposed on the first mask layer. The second mask layer includes a metal layer having a metal opening formed therein and an inorganic layer disposed on the metal layer and having an inorganic opening overlapping the first mask opening in a plan view. The metal opening overlaps the inorganic opening in a plan view.

### CROSS-REFERENCE TO RELATED APPLICATION(S)

This application claims priority to and benefits of Korean Patent Application No. 10-2023-0039061, filed on Mar. 24, 2023, in the Korean Intellectual Property Office (KIPO), and Korean Patent Application No. 10-2023-0080675, filed on Jun. 22, 2023, in the Korean Intellectual Property Office (KIPO), under 35 U.S.C. § 119, the entire contents of which are incorporated herein by reference.

### BACKGROUND

### 1. Technical Field

Embodiments relate to an apparatus and method for manufacturing a display device.

### 2. Description of the Related Art

Display devices are used to visually display data. Display devices may provide images by using light-emitting diodes. Display devices are used for various purposes. Accordingly, various designs have been attempted to improve the quality of a display device.

### SUMMARY

Embodiments include an apparatus for manufacturing a display device including a mask assembly with magnetism, in which a manufacturing process of the display device is simplified.

However, such an objective is an example, and the objective to be solved by the disclosure is not limited thereto.

Additional aspects will be set forth in part in the description which follows and, in part, will be apparent from the description, or may be learned by practice of the embodiments of the disclosure.

According to an embodiment, an apparatus for manufacturing a display device may include a chamber, a mask assembly arranged in the chamber and facing a display substrate, a magnetic force portion arranged in the chamber and applying a magnetic force to the mask assembly, and a deposition source arranged in the chamber, facing the mask assembly, and supplying a deposition material to deposit on the display substrate by passing through the mask assembly. The mask assembly may include a first mask layer having a first mask opening formed therein, and a second mask layer disposed on the first mask layer. The second mask layer may include a metal layer having a metal opening formed therein, and an inorganic layer disposed on the metal layer and having an inorganic opening overlapping the first mask opening in a plan view. The metal opening may overlap the inorganic opening in a plan view.

In an embodiment, in a plan view, the metal layer may surround the inorganic opening.

In an embodiment, at least a part of the inorganic layer may be arranged within the metal opening.

In an embodiment, the metal layer may include a plurality of metal layers.

In an embodiment, in a plan view, the plurality of metal layers may be spaced apart from each other by a distance.

In an embodiment, in a cross-sectional view, at least a part of the inorganic layer may be arranged between the plurality of metal layers.

In an embodiment, a lower surface of the metal layer may be exposed from the inorganic layer.

In an embodiment, the inorganic layer may cover an upper surface of the metal layer.

According to an embodiment, a method of manufacturing a display device may include arranging a display substrate in a chamber, arranging a mask assembly in the chamber, applying, by a magnetic force portion, a magnetic force to the mask assembly, and supplying, by a deposition source, a deposition material toward the mask assembly. The arranging of the mask assembly may include disposing a metal layer on a first mask layer, forming a metal opening in the metal layer, disposing an inorganic layer on the metal layer, forming a first mask opening in the first mask layer, and forming an inorganic opening in the inorganic layer overlapping the metal opening in a plan view.

In an embodiment, the forming of the inorganic opening in the inorganic layer may include etching the inorganic layer in a direction in which the first mask layer faces the metal layer.

In an embodiment, a lower portion of the metal layer may be exposed from the inorganic layer, according to the etching of the inorganic layer.

In an embodiment, the metal layer may surround the inorganic opening, according to the forming of an inorganic opening in the inorganic layer.

In an embodiment, at least a part of the inorganic layer may be arranged within the metal opening, according to the arranging of the inorganic layer.

In an embodiment, the metal layer may include a plurality of metal layers.

In an embodiment, in a plan view, the plurality of metal layers may be spaced apart from each other by a distance.

In an embodiment, in a cross-sectional view, at least a part of the inorganic layer may be arranged between the plurality of metal layers.

In an embodiment, the inorganic layer may cover an upper surface of the metal layer, according to the arranging of the inorganic layer.

Other aspects, features, and advantages than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display device, according to an embodiment;

FIG. 2 is a schematic cross-sectional view of a mask assembly according to an embodiment;

FIG. 3 is a schematic plan view of a portion of a second mask layer according to an embodiment;

FIGS. 4 to 11 are schematic cross-sectional views of a mask assembly illustrating a method of manufacturing a display device, according to an embodiment;

FIG. 12 is a schematic perspective view of a display device according to an embodiment;

FIG. 13 is a schematic cross-sectional view of a display device according to an embodiment;

FIG. 14 is a schematic plan view of a display panel according to an embodiment;

FIG. 15 is a schematic diagram of an equivalent circuit of a pixel included in a display device according to an embodiment; and

FIG. 16 is a schematic cross-sectional view of a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the embodiments, and particular embodiments will be illustrated in the drawings and described in the detailed description section. The effect and features of the embodiments, and a method to achieve the same, will be clearer referring to the detailed descriptions below with the drawings. However, the embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the following embodiment, the x axis, the y axis, and the z axis are not limited to three axes of the rectangular coordinate system, and may be interpreted in a broader sense. For example, the x axis, the y axis, and the z axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

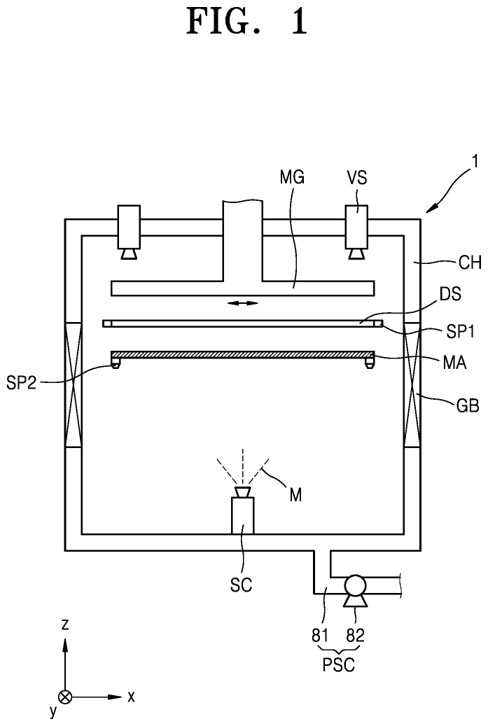

FIG. 1 is a schematic cross-sectional view of an apparatus 1 for manufacturing a display device, according to an embodiment.

The apparatus 1 for manufacturing a display device may include a chamber CH, a first support portion SP1, a second support portion SP2, a mask assembly MA, a deposition source SC, a magnetic force portion MG, a vision portion VS, and a pressure control portion PSC.

The chamber CH may have a space formed therein, and a display substrate DS and the mask assembly MA may be accommodated in the chamber CH. An open portion may be formed in a portion of the chamber CH, a gate valve GB may be installed on the open portion of the chamber CH, and the open portion of the chamber CH may be opened or closed according to an operation of the gate valve GB.

The display substrate DS may be a display substrate in the course of manufacturing a display device, in which at least one of an organic layer, an inorganic layer, and a metal layer is deposited on the substrate 100 described below. In another embodiment, the display substrate DS may be a display substrate in which any of an organic layer, an inorganic layer, and a metal layer is not deposited yet.

The first support portion SP1 may support the display substrate DS. The first support portion SP1 may be in a form of a plate fixed in the chamber CH. In another embodiment, the first support portion SP1 may be in a form of a shuttle placed on the display substrate DS and capable of linear motion inside the chamber CH. In another embodiment, the first support portion SP1 may include an electrostatic chuck or an adhesive chuck arranged in the chamber CH and fixed to the chamber CH or movable inside the chamber CH.

The second support portion SP2 may support the mask assembly MA. The second support portion SP2 may be arranged inside the chamber CH. The second support portion SP2 may finely control the position of the mask assembly MA. The second support portion SP2 may include a separate driving portion, an alignment unit, and the like to move the mask assembly MA in a direction.

In another embodiment, the second support portion SP2 may be in a form of a shuttle, and the mask assembly MA may be placed on the second support portion SP2, thus, the second support portion SP2 may transfer the mask assembly MA. For example, the second support portion SP2 may be moved outside the chamber CH, and after the mask assembly MA is placed on the second support portion SP2, the second support portion SP2 may enter the chamber CH from the outside of the chamber CH.

In the above embodiment, the first support portion SP1 and the second support portion SP2 may be integrally formed with each other, and the first support portion SP1 and the second support portion SP2 may include a movable shuttle. The first support portion SP1 and the second support portion SP2 may have a structure of fixing the mask assembly MA and the display substrate DS while the display substrate DS is placed on the mask assembly MA, and may simultaneously linearly move the display substrate DS and the mask assembly MA.

However, in the following description, for convenience of explanation, an embodiment in which the first support portion SP1 and the second support portion SP2 are separately formed and located at different positions, and the first support portion SP1 and the second support portion SP2 are arranged inside the chamber CH, is described in detail.

The mask assembly MA may be arranged inside the chamber CH and face the display substrate DS. A deposition material M may pass through the mask assembly MA to be deposited on the display substrate DS.

The deposition source SC may be arranged and face the mask assembly MA, and the deposition material M may be supplied to be deposited on the display substrate DS by passing through the mask assembly MA. The deposition source SC may evaporate or sublimate the deposition material M by applying heat to the deposition material M. The deposition source SC may be arranged to be fixed inside of the chamber CH or arranged inside the chamber CH to be capable of linear motion in a direction.

The magnetic force portion MG may be arranged inside the chamber CH and face the display substrate DS and/or the mask assembly MA. The magnetic force portion MG may apply a magnetic force to the mask assembly MA toward the display substrate DS.

The vision portion VS may be arranged in the chamber CH and may detect the positions of the display substrate DS and the mask assembly MA. The vision portion VS may include a camera for detecting the display substrate DS and the mask assembly MA. The positions of the display substrate DS and the mask assembly MA may be identified based on an image captured by the vision portion VS, and misalignment of the mask assembly MA may be checked. Furthermore, based on the image, the first support portion SP1 may finely adjust the position of the display substrate DS, or the second support portion SP2 may finely adjust the position of the mask assembly MA. However, in the following description, an embodiment in which the second support portion SP2 finely adjusts the position of the mask assembly MA to align the positions of the display substrate DS and the mask assembly MA is described in detail.

The pressure control portion PSC may be connected to the chamber CH and may control pressure in the chamber CH. For example, the pressure control portion PSC may control the pressure in the chamber CH to be the same as or similar to the atmospheric pressure. For example, the pressure control portion PSC may control the pressure in the chamber CH to be the same as or similar to a vacuum state.

The pressure control portion PSC may include a connection pipe 81 connected to the chamber CH and a pump 82 installed on the connection pipe 81. According to the operation of the pump 82, external air may be introduced through the connection pipe 81, or a gas in the chamber CH may be exhausted to the outside through the connection pipe 81.

In a method of manufacturing a display device (not shown) by using the apparatus 1 for manufacturing a display device, first, a display substrate DS may be prepared.

The pressure control portion PSC may maintain the inside of the chamber CH in a state that is the same as or similar to the atmospheric pressure, and the open portion of the chamber CH may be opened by operating the gate valve GB.

The display substrate DS may be loaded into the chamber CH from the outside. The display substrate DS may be loaded into the chamber CH in various manners. For example, the display substrate DS may be loaded into the chamber CH from the outside by a robot arm and the like arranged outside the chamber CH. In another embodiment, in case that the first support portion SP1 is in the form of a shuttle, the first support portion SP1 may move from the inside of the chamber CH to the outside of the chamber CH, the display substrate DS may be placed on the first support portion SP1 by a separate robot arm and the like arranged outside the chamber CH, and the first support portion SP1 may be loaded into the chamber CH from the outside the chamber CH.

The mask assembly MA may be arranged inside the chamber CH as described above. In another embodiment, the mask assembly MA may be loaded into the chamber CH from the outside the chamber CH in the same or similar way as the display substrate DS.

In case that the display substrate DS is loaded into the chamber CH, the display substrate DS may be placed on the first support portion SP1. The vision portion VS may capture the positions of the display substrate DS and the mask assembly MA. The positions of the display substrate DS and the mask assembly MA may be identified based on the image captured by the vision portion VS. The apparatus 1 for manufacturing a display device may be provided with a separate controller (not shown) to identify the positions of the display substrate DS and the mask assembly MA.

After the identification of the positions of the display substrate DS and the mask assembly MA is completed, the second support portion SP2 may finely adjust the position of the mask assembly MA.

The deposition source SC may be operated to supply the deposition material M toward the mask assembly MA, and the deposition material M having passed through the mask assembly MA may be deposited on the display substrate DS. The deposition source SC may move parallel to the display substrate DS and the mask assembly MA, or the display substrate DS and the mask assembly MA may move parallel to the deposition source SC. For example, the deposition source SC may move relative to the display substrate DS and the mask assembly MA, and the pump 82 may draw the gas in the chamber CH and discharge the gas to the outside so that the pressure in the chamber CH may be maintained in a state that is the same as or similar to vacuum.

As described above, the deposition material M supplied from the deposition source SC may pass through the mask assembly MA and deposited on the display substrate DS. Accordingly, at least one of multiple layers, for example, an organic layer, an inorganic layer, and a metal layer to be stacked on a display device described below may be formed.

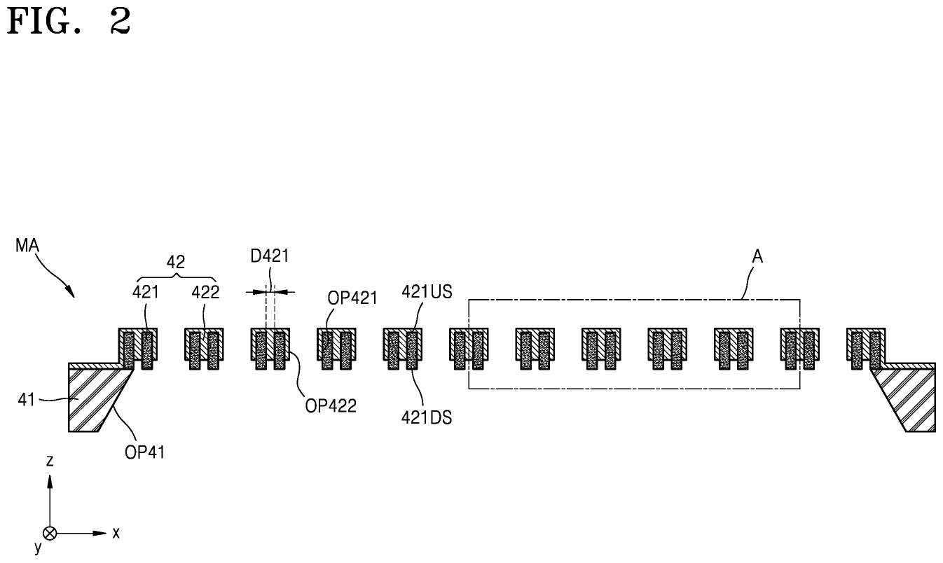

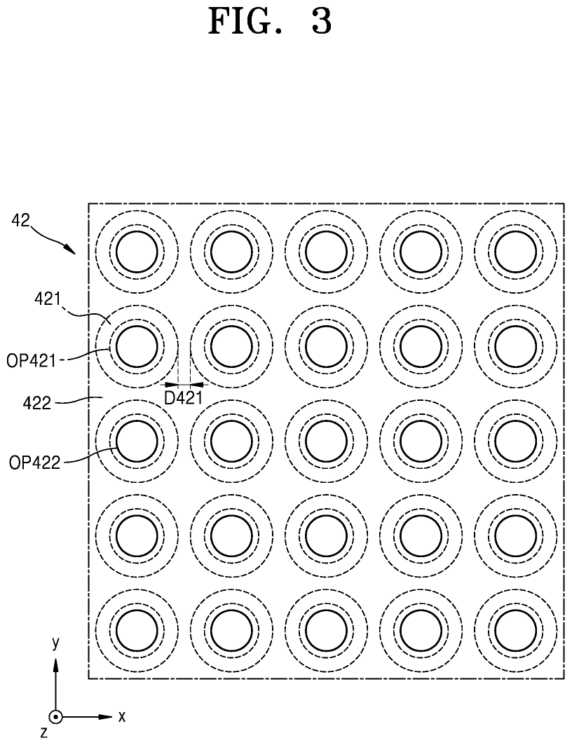

FIG. 2 is a schematic cross-sectional view of the mask assembly MA according to an embodiment, and FIG. 3 is a schematic plan view of a portion of a second mask layer according to an embodiment. For example, FIG. 3 shows region A of FIG. 2 in a plan view.

Referring to FIGS. 2 and 3, the mask assembly MA may include a first mask layer 41 and a second mask layer 42.

A first mask opening OP41 may be arranged in the first mask layer 41, and the deposition material M (see FIG. 1) may pass through the first mask opening OP41. An inner circumferential surface may be formed on the first mask layer 41 by the first mask opening OP41. The first mask opening OP41 may be arranged at a central portion of the first mask layer 41. The central portion of the second mask layer 42 may be exposed through the first mask opening OP41 of the first mask layer 41. Although FIG. 2 illustrates that the inner circumferential surface of the first mask layer 41 is inclined with respect to the second mask layer 42, the disclosure is not limited thereto, and the inner circumferential surface of the first mask layer 41 may be perpendicular to the second mask layer 42.

The first mask layer 41 may include a silicon material. For example, the first mask layer 41 may include at least one of a silicon oxide (SiOₓ), a silicon nitride (SiNₓ), and a silicon oxynitride (SiOₓN_{y}).

The second mask layer 42 may be disposed on the first mask layer 41. The second mask layer 42 may be formed on the first mask layer 41. The second mask layer 42 may include a metal layer 421 and an inorganic layer 422.

The metal layer 421 may be disposed on the first mask layer 41. The metal layer 421 may be magnetic. For example, the metal layer 421 may include at least one of aluminum (AI), copper (Cu), titanium (Ti), and molybdenum (Mo).

The metal layer 421 may be supported on the first mask layer 41 by the inorganic layer 422. A metal opening OP421 may be arranged in the metal layer 421. The metal opening OP421 may overlap the first mask opening OP41 in a plan view. The metal layer 421 may include multiple metal layers 421. As illustrated in FIG. 3, in a plan view, the metal layers 421 may be arranged spaced apart from each other by a first distance D421. For example, as illustrated in FIG. 3, the metal openings OP421 may be arranged in a first direction (e.g., a y axis direction) and a second direction (e.g., an x axis direction).

The inorganic layer 422 may be disposed on the first mask layer 41 and the metal layer 421. The inorganic layer 422 may be supported on the first mask layer 41. The inorganic layer 422 may include at least one of SiOₓ, SiNₓ, and SiOxN_{y}.

An inorganic opening OP422 overlapping the first mask opening OP41 and the metal opening OP421 in a plan view may be arranged in the inorganic layer 422. The inorganic opening OP422 may overlap the first mask opening OP41 in a plan view. The inorganic opening OP422 may include multiple inorganic openings OP422. For example, as illustrated in FIG. 3, the inorganic openings OP422 may be arranged in the first direction (e.g., the y axis direction) and the second direction (e.g., the x axis direction).

The position of an inorganic opening OP422 may correspond to the position of a metal opening OP421. As illustrated in FIG. 3, in a plan view, a width of the metal opening OP421 may be greater than a width of the inorganic opening OP422. In this structure, at least a part of the inorganic layer 422 may be arranged in the metal opening OP421. As illustrated in FIG. 3, in a plan view, the width of the metal opening OP421 may be greater than the width of the inorganic opening OP422. In other words, in a plan view, the metal layer 421 may surround the inorganic opening OP422.

The inorganic layer 422 may cover the metal layer 421. For example, the inorganic layer 422 may cover an upper surface of the metal layer 421. In case that the metal layer 421 includes multiple metal layers 421, at least a part of the inorganic layer 422 may be disposed on the metal layers 421. A part of the metal layer 421 may be exposed from the inorganic layer 422. For example, a lower surface 421 DS of the metal layer 421 may be exposed from the inorganic layer 422.

Due to the arrangement of the metal layer 421 with magnetism, the magnetic force portion MG may apply a magnetic force to the mask assembly MA. In other words, gravity may work between the mask assembly MA and the magnetic force portion MG. Accordingly, the mask assembly MA and the display substrate DS may closely contact each other. Accordingly, an error occurring in a process of depositing the display substrate DS may be reduced.

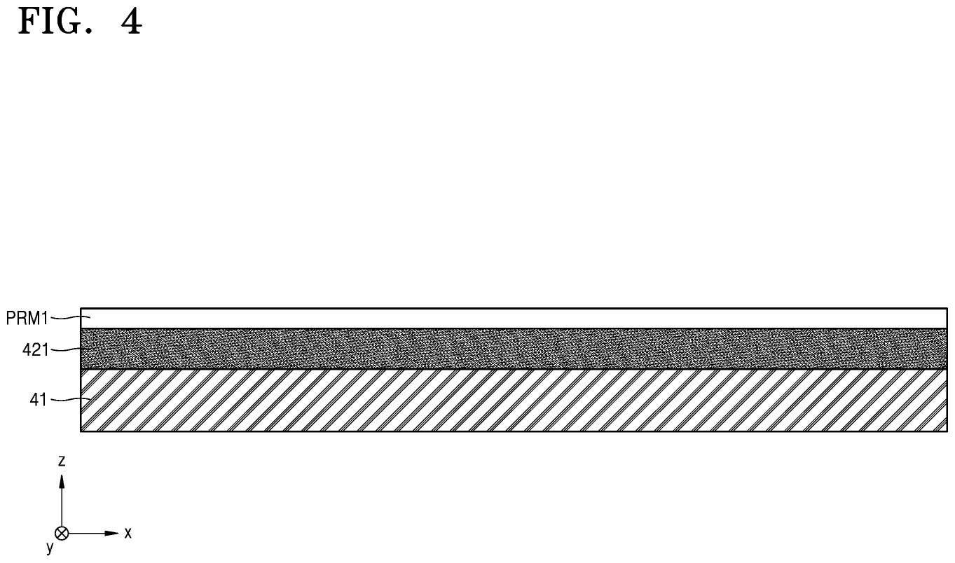

FIGS. 4 to 11 are schematic cross-sectional views of the mask assembly MA illustrating a method of manufacturing a display device, according to an embodiment.

In FIGS. 4 to 11, like elements in FIGS. 1 to 3 are denoted by like reference numerals, and redundant descriptions thereof are omitted.

Referring to FIGS. 4 to 11, a method of manufacturing a display device may include arranging the mask assembly MA in the chamber CH (see FIG. 1).

The arranging of the mask assembly MA may include disposing the metal layer 421 on the first mask layer 41, forming the metal opening OP421 in the metal layer 421, disposing the inorganic layer 422 on the metal layer 421, forming the first mask opening OP41 in the first mask layer 41, and forming the inorganic opening OP422 in the inorganic layer 422.

Referring to FIGS. 4 to 8, the disposing of the metal layer 421 on the first mask layer 41 and the forming of the metal opening OP421 in the metal layer 421 may be described.

First, referring to FIG. 4, the metal layer 421 may be disposed on the first mask layer 41, and a first photoresist material PRM1 may be disposed on the metal layer 421. The first photoresist material PRM1 may include a photosensitive material.

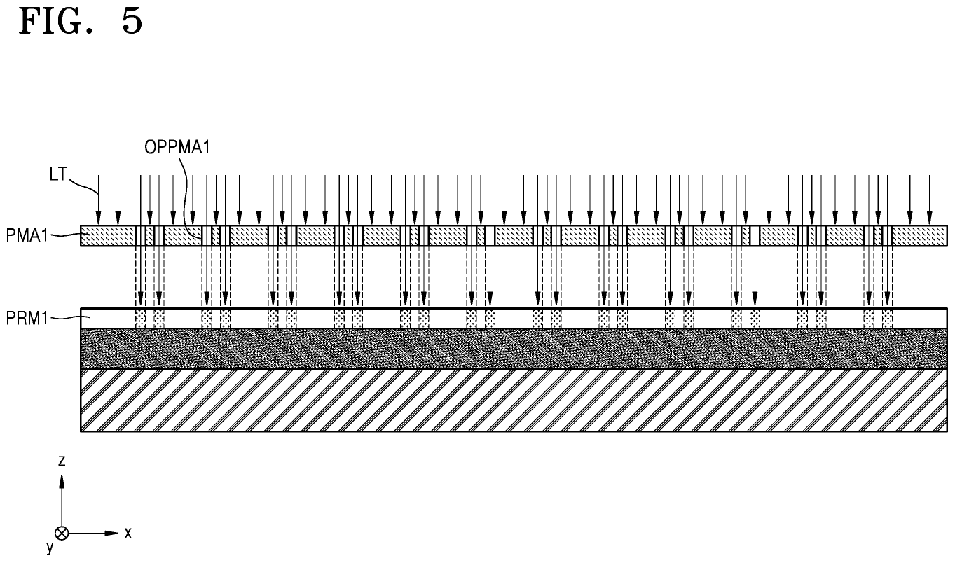

Referring to FIG. 5, a first photo mask PMA1 in which a first photo mask opening OPPMA1 is arranged may be disposed above the first photoresist material PRM1. The first photoresist material PRM1 may be exposed to light LT through the first photo mask opening OPPMA1. The light LT may pass through the first photo mask opening OPPMA1 to be incident on the first photoresist material PRM1. For example, the light LT may be ultraviolet. In the process, the solubility of the first photoresist material PRM1 that overlaps the first photo mask opening OPPMA1 in a plan view may be reduced. Furthermore, the solubility of the first photoresist material PRM1 that does not overlap the first photo mask opening OPPMA1 in a plan view may be increased.

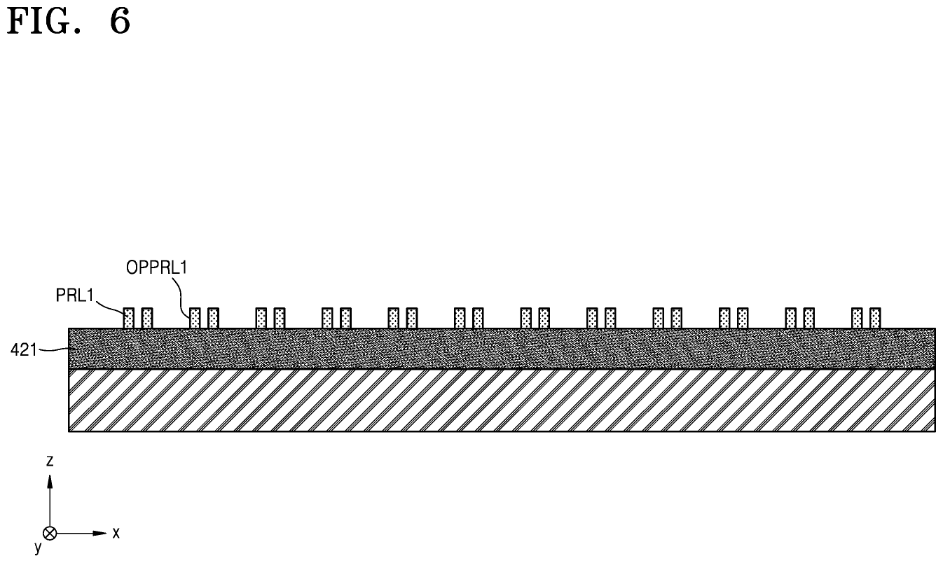

Referring to FIG. 6, the first photoresist material PRM1 may be developed into a first photoresist layer PRL1. For example, a part of the first photoresist material PRM1 may be removed by using an alkali developer. The first photoresist material PRM1 that does not contact light LT in FIG. 5 may be removed.

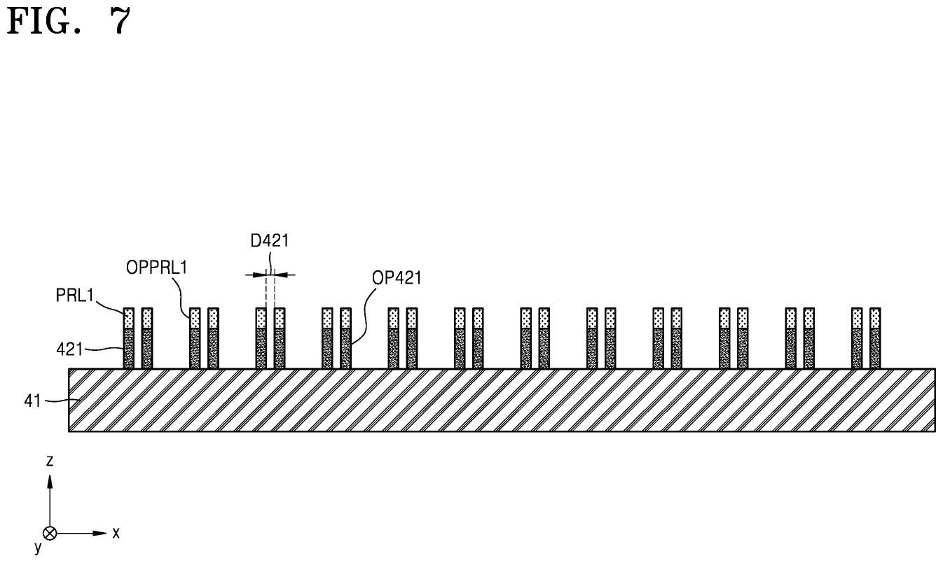

Referring to FIG. 7, a part of the metal layer 421 overlapping a first photo opening OPPRL1 in a plan view may be etched. The metal layer 421 may be etched in a direction (e.g., a −z axis direction) in which the metal layer 421 faces the first mask layer 41. A part of the metal layer 421 overlapping the first photoresist layer PRL1 in a plan view may be left, and a part of the metal layer 421 overlapping the first photo opening OPPRL1 in a plan view may be removed. As the metal layer 421 is etched, the metal opening OP421 may be formed in the metal layer 421.

As the first photo opening OPPRL1 includes multiple first photo openings OPPRL1, the metal layer 421 may also include multiple metal layers 421. The metal layers 421 may be spaced apart from each other by the first distance D421. As the metal layer 421 is etched, the first mask layer 41 may be exposed from the metal layer 421 through the metal opening OP421. For example, the metal layer 421 may be etched by dry etching using an etching gas.

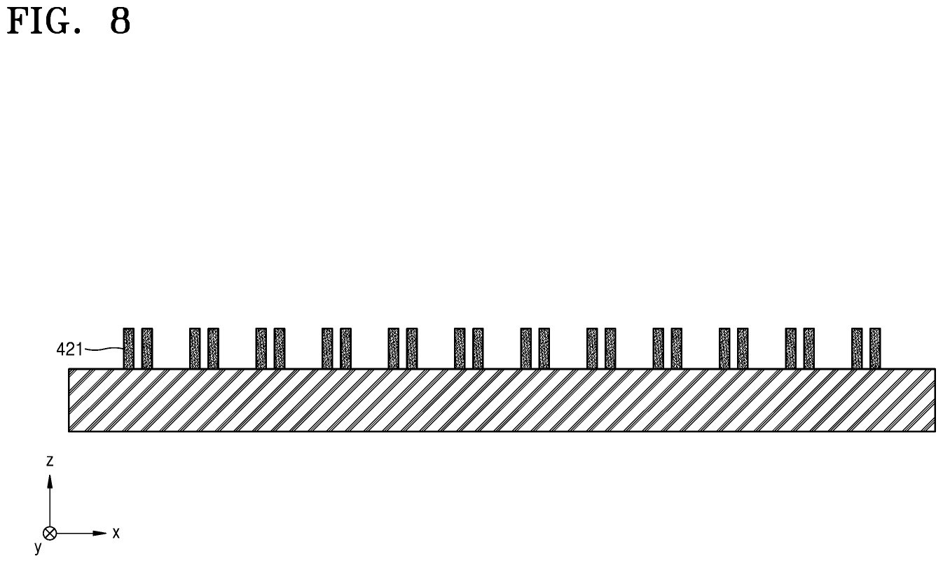

Referring to FIG. 8, the first photoresist layer PRL1 (see FIG. 7) may be removed. As the first photoresist layer PRL1 is removed, the upper surface of the metal layer 421 may be exposed.

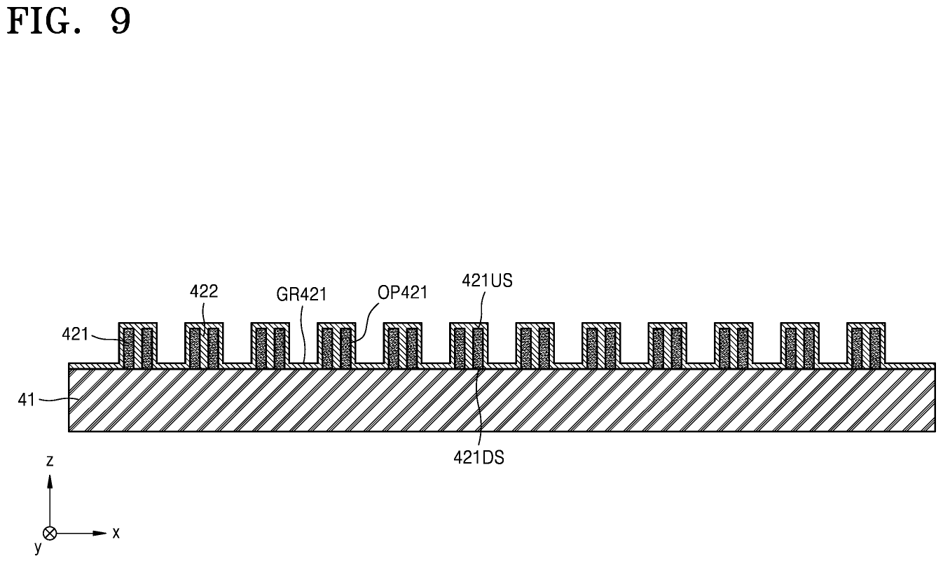

Referring to FIG. 9, the disposing of the inorganic layer 422 on the metal layer 421 is described. At least a part of the inorganic layer 422 may be arranged in the metal opening OP421 and contact the first mask layer 41. A part of the inorganic layer 422 may be accommodated between the metal layers 421 and contact the first mask layer 41. The inorganic layer 422 may cover an upper surface 421 US of the metal layer 421, and the lower surface 421 DS of the metal layer 421 may contact the first mask layer 41. The metal layer 421 may be sealed by the first mask layer 41 and the inorganic layer 422. A first groove GR421 may be formed in the inorganic layer 422 corresponding to the shape of the metal layer 421.

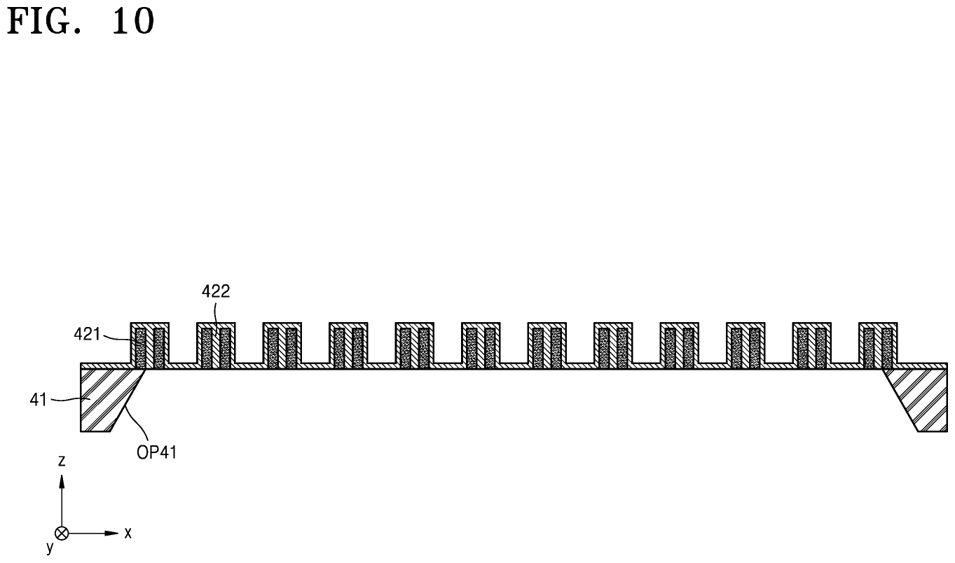

Referring to FIG. 10, the forming of the first mask opening OP41 in the first mask layer 41 is described. The first mask opening OP41 may be formed by a photolithography process. As the photolithography process is described above with reference to FIGS. 4 to 8, a detailed description thereof is omitted. As the first mask opening OP41 is formed, the lower surfaces of the metal layer 421 and the inorganic layer 422 may be exposed from the first mask layer 41 through the first mask opening OP41.

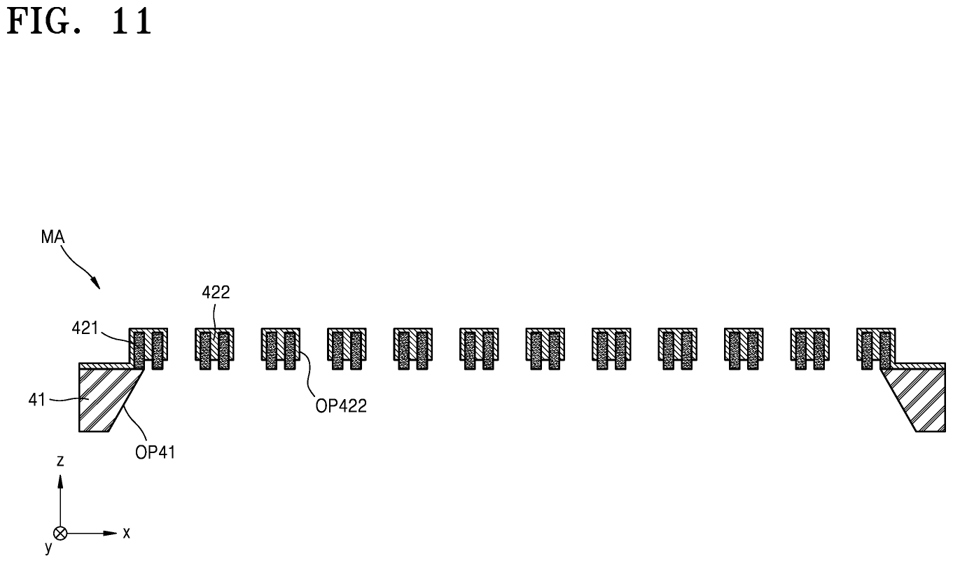

Referring to FIG. 11, the forming of the inorganic opening OP422 in the inorganic layer 422 is described. The forming of the inorganic opening OP422 in the inorganic layer 422 may include etching the inorganic layer 422 in a direction (e.g., a +z axis direction) in which the first mask layer 41 faces the metal layer 421. As a lower portion of the inorganic layer 422 is etched, the inorganic opening OP422 may be formed in the inorganic layer 422. Furthermore, the lower portion of the metal layer 421 may be exposed from the inorganic layer 422. As the inorganic opening OP422 is formed in the inorganic layer 422, the metal layer 421 may surround the inorganic opening OP422.

In the process, the inorganic opening OP422 may be formed without a photolithography process. In other words, the inorganic opening OP422 may be formed without a separate photoresist material and a photo mask. Accordingly, the mask assembly MA manufacturing process may be simplified. For example, the inorganic layer 422 may be etched through a dry etching using an etching gas.

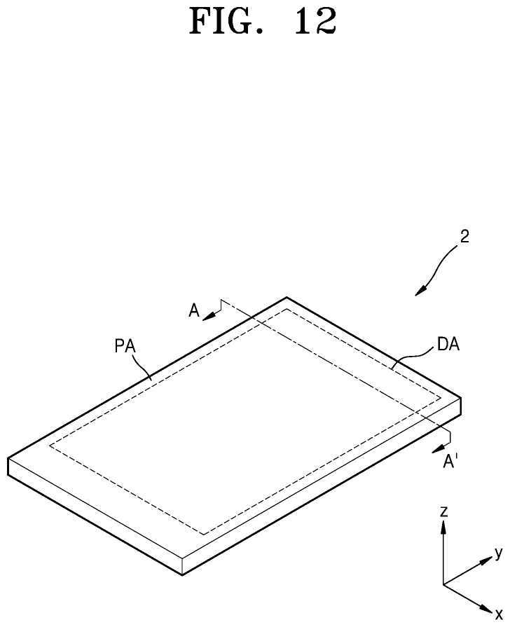

FIG. 12 is a schematic perspective view of a display device 2 according to an embodiment.

Referring to FIG. 12, the display device 2 may include a display area DA and a peripheral area PA adjacent to (e.g., surrounding) the display area DA. The display device 2 may provide image by using light emitted from multiple pixels arranged in the display area DA.

The peripheral area PA may entirely surround the display area DA in a plan view. The peripheral area PA may be a non-display area in which pixels are not arranged, and drivers or wires for providing electrical signals or power to the pixels may be arranged in the peripheral area PA.

The display device 2 may have a rectangular shape in a plan view in which a horizontal length is greater than a vertical length as illustrated in FIG. 12, but the disclosure is not limited thereto. The display device 2 may have various shapes, such as a polygonal shape, a circular shape, or an oval shape.

In the following description, although an organic light-emitting display device is described as an embodiment of the display device 2, the display device is not limited thereto. In another embodiment, display devices of different types, such as a quantum-dot light-emitting display device, may be used therefor.

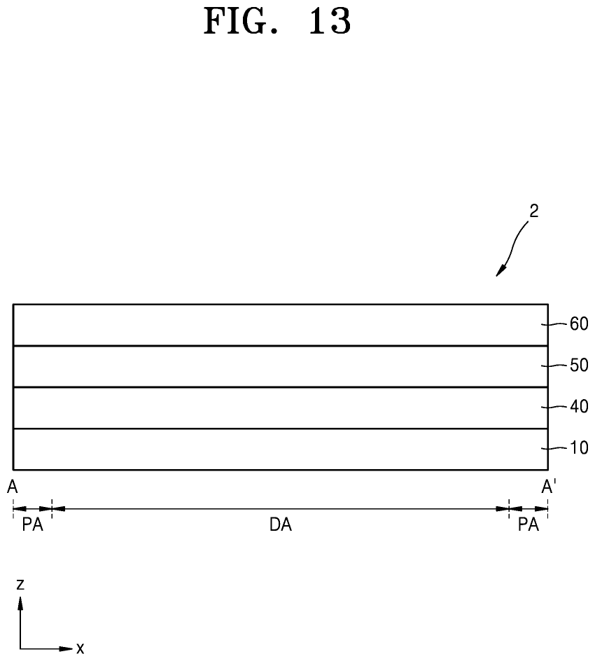

FIG. 13 is a schematic cross-sectional view of the display device 2 according to an embodiment. FIG. 13 may correspond to line A-A′ of FIG. 12.

Referring to FIG. 13, the display device 2 may include a display panel 10, an input sensing layer 40 disposed on the display panel 10, and an optical function layer 50, which are covered by a window 60. The display device 2 may be various types of electronic devices, such as mobile phones, notebook computers, smart watches, and the like.

The display panel 10 may display an image. The display panel 10 may include pixels arranged in the display area DA. The pixels may include a display element and a pixel circuit connected to the display element. The display element may include an organic light-emitting diode, a quantum-dot organic light-emitting diode, or the like.

The input sensing layer 40 may obtain coordinate information according to an external input, for example, a touch event. The input sensing layer 40 may include a sensing electrode (or a touch electrode) and trace lines connected to the sensing electrode. The input sensing layer 40 may be disposed on the display panel 10. The input sensing layer 40 may sense an external input by a mutual cap method or/and a self-cap method.

The input sensing layer 40 may be formed (e.g., directly formed) on the display panel 10, or may be separately formed and coupled through an adhesive layer such as an optically clear adhesive. For example, the input sensing layer 40 may be continuous formed after a process of forming the display panel 10, and the input sensing layer 40 may be a part of the display panel 10, and no adhesive layer may be provided between the input sensing layer 40 and the display panel 10. Although FIG. 13 illustrates that the input sensing layer 40 is provided between the display panel 10 and the optical function layer 50, the disclosure is not limited thereto, and in another embodiment, the input sensing layer 40 may be disposed on the optical function layer 50.

The optical function layer 50 may include an antireflective layer. The antireflective layer may reduce reflectivity of light (external light) input to the display panel 10 from the outside through the window 60. In an embodiment, the antireflective layer may include a black matrix and color filters. The color filters may be arranged considering the color of light emitted from each of the pixels of the display panel 10.

In another embodiment, the antireflective layer may include a retarder and a polarizer. The retarder may be of a film type or a liquid crystal coating type, or may include a λ/2 retarder and/or a λ/4 retarder. The polarizer may also be of a film type or a liquid crystal coating type. The film type of the polarizer may include a stretchable synthetic resin film, and the liquid crystal coating type of the polarizer may include liquid crystals arranged in an array. The retarder and the polarizer may further include a protective film. The retarder and the polarizer themselves or the protective film may be defined as a base layer of the antireflective layer.

In another embodiment, the antireflective layer may include a destructive interference structure. The destructive interference structure may include a first reflective layer and a second reflective layer disposed on different layers. First reflected light and second reflected light respectively reflected from the first reflective layer and the second reflective layer may destructively interfere with each other so that the reflectivity of external light may be reduced.

In an embodiment, the optical function layer 50 may be continuously formed after the process of forming the display panel 10 and/or the input sensing layer 40, and an adhesive layer may not be provided between the optical function layer 50, the display panel 10, and/or the input sensing layer 40.

Although not illustrated in FIG. 13, a layer including an optically clear adhesive, optically clear resin, or the like may be located between the window 60 and the optical function layer 50.

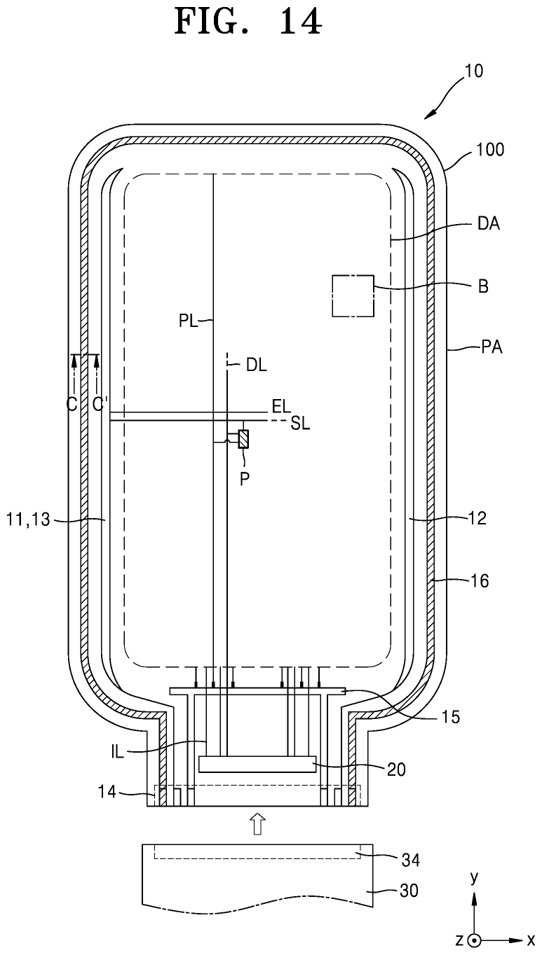

FIG. 14 is a schematic plan view of a display panel according to an embodiment. As described with reference to FIG. 13, the display device 2 according to an embodiment may include the display panel 10. FIG. 14 may correspond to the shape of the substrate 100 of the display panel 10.

Referring to FIG. 14, the display panel 10 may include the display area DA and the peripheral area PA adjacent to the display area DA. The display area DA may be a portion for displaying an image, and multiple pixels P may be arranged in the display area DA. The display area DA may have various shapes in a plan view, such as a circular shape, an oval shape, a polygonal shape, a specific figure shape, and the like. FIG. 14 illustrates that the display area DA has a rectangular shape with approximately round corners, but the disclosure is not limited thereto.

Each of the pixels P may be a sub-pixel, and may include a display element such as an organic light-emitting diode OLED. The pixel P may emit, for example, red, green, blue, or white light.

The peripheral area PA may be arranged adjacent to the display area DA. Outer circuits for driving the pixel P may be arranged in the peripheral area PA. A first scan drive circuit 11, a second scan drive circuit 12, an emission control drive circuit 13, a terminal 14, a driving power supply wire 15, and a common power supply wire 16 may be arranged in the peripheral area PA.

The first scan drive circuit 11 may provide a scan signal to the pixel P through a scan line SL. The second scan drive circuit 12 may be arranged parallel to the first scan drive circuit 11 with the display area DA between the first scan drive circuit 11 and the second scan drive circuit 12. Some of the pixels P arranged in the display area DA may be electrically connected to the first scan drive circuit 11, and others may be electrically connected to the second scan drive circuit 12. In another embodiment, the second scan drive circuit 12 may be omitted, and the pixels P arranged in the display area DA may all be electrically connected to the first scan drive circuit 11.

The emission control drive circuit 13 may be arranged adjacent to the first scan drive circuit 11, and may provide an emission control signal to the pixel P through an emission control line EL. Although FIG. 12 illustrates that the emission control drive circuit 13 is arranged at only one side of the display area DA, the disclosure is not limited thereto, and the emission control drive circuit 13 may be arranged at both sides of the display area DA, like the first scan drive circuit 11 and the second scan drive circuit 12.

In an embodiment, the peripheral area PA may include a bending area extending from a side of the display area DA (a −y direction). The bending area may be bendable toward a rear surface of the display area DA, so that the area of a non-display area being perceived from the front surface of the display device 2 may be reduced.

A driving chip 20 may be arranged in the peripheral area PA. The driving chip 20 may include an integrated circuit for driving the display panel 10. The integrated circuit may include a data driving integrated circuit for generating a data signal, but the disclosure is not limited thereto.

The terminal 14 may be arranged in the peripheral area PA. The terminal 14 may be exposed without being covered by an insulating layer and may be electrically connected to a printed circuit board 30. A terminal 34 of the printed circuit board 30 may be electrically connected to the terminal 14 of the display panel 10.

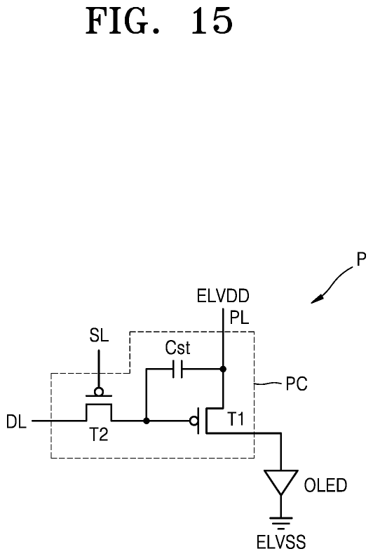

The printed circuit board 30 may transmit a signal or power of a controller (not shown) to the display panel 10. The control signal generated by the controller may be transmitted to the drive circuits through the printed circuit board 30. Furthermore, the controller may transmit a driving voltage ELVDD (see FIG. 15) to the driving power supply wire 15, and a common voltage ELVSS (see FIG. 15) to the common power supply wire 16. The driving voltage ELVDD may be transmitted to each pixel P through a driving voltage line PL connected to the driving power supply wire 15, and the common voltage ELVSS may be transmitted to a counter electrode of the pixel P connected to the common power supply wire 16. The driving power supply wire 15 may have a shape extending in a direction (the x axis direction) below the display area DA in a plan view. The common power supply wire 16 may have a loop shape with an open side, and may have a shape partially surrounding the display area DA in a plan view.

The controller may generate a data signal, and the generated data signal may be transmitted to an input line IL through the driving chip 20, and to the pixel P through a data line DL connected to the input line IL. For example, a “line” may be a “wire.” The same applies to embodiments described below.

FIG. 15 is a schematic diagram of an equivalent circuit of a pixel P included in a display device according to an embodiment.

Referring to FIG. 15, one pixel P may be a display element including a pixel circuit PC and the organic light-emitting diode OLED connected to the pixel circuit PC. The pixel circuit PC may include a first thin film transistor T1, a second thin film transistor T2, and a storage capacitor Cst. Each pixel P may emit, for example, red, green, or blue light, or red, green, blue, or white light, through the organic light-emitting diode OLED.

The second thin film transistor T2, as a switching thin film transistor, may be connected to the scan line SL and the data line DL, and may transmit a data voltage input through the data line DL to the first thin film transistor T1, based on a switching voltage input through the scan line SL. The storage capacitor Cst may be connected to the second thin film transistor T2 and the driving voltage line PL, and may store a voltage corresponding to a difference between the voltage received from the second thin film transistor T2 and the driving voltage ELVDD provided through the driving voltage line PL.

The first thin film transistor T1, as a driving thin film transistor, may be connected to the driving voltage line PL and the storage capacitor Cst, and may control a driving current flowing in the organic light-emitting diode OLED from the driving voltage line PL in response to a value of the voltage stored in the storage capacitor Cst. The organic light-emitting diode OLED may emit light having a luminance corresponding to the driving current. A counter electrode (e.g., a cathode) of the organic light-emitting diode OLED may receive the common voltage ELVSS.

Although FIG. 15 illustrates that the pixel circuit PC includes two thin film transistors and one storage capacitor, the disclosure is not limited thereto. The number of thin film transistors and the number of storage capacitors may vary depending on the design of the pixel circuit PC. For example, the pixel circuit PC may include four or more thin film transistors in addition to the two thin film transistors described above.

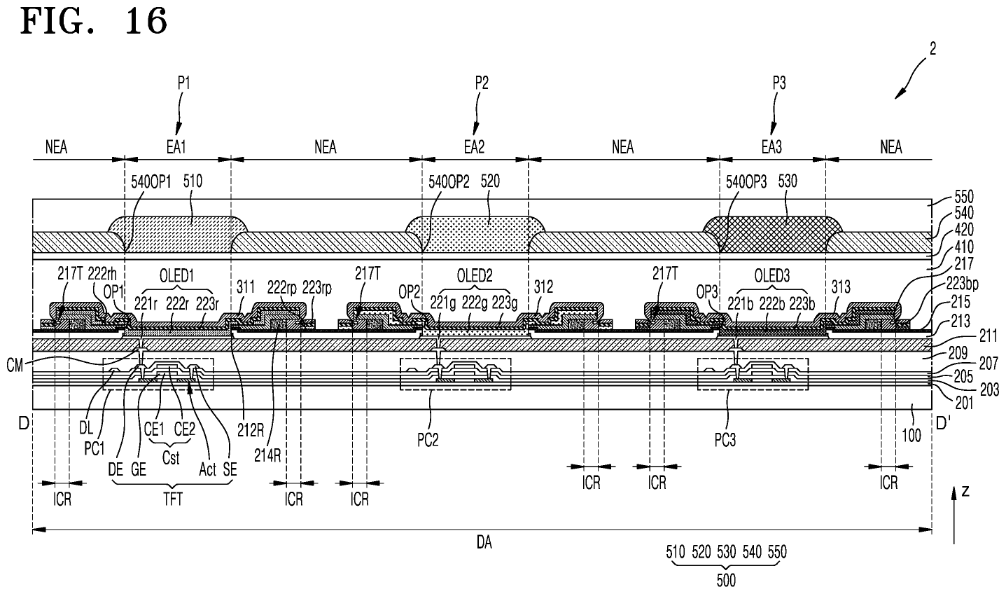

FIG. 16 is a schematic cross-sectional view of the display device 2 according to an embodiment.

Referring to FIG. 16, the display panel 10 may include the substrate 100.

The substrate 100 may include a glass material or a polymer resin. In an embodiment, the substrate 100 may have a multilayer structure in which a base layer including a polymer resin and a barrier layer for preventing infiltration of external foreign materials are alternately stacked each other.

The base layer may include a polymer resin including polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), cellulose triacetate (TAC), cellulose acetate propionate (CAP), or the like.

The barrier layer may include an inorganic material, such as a silicon nitride (SiNₓ), a silicon oxide (SiOₓ), and the like.

A first pixel P1 for emitting light of a first color, a second pixel P2 for emitting light of a second color, and a third pixel P3 for emitting light of a third color may be arranged in the display area DA of the substrate 100. The first color, the second color, and the third color may each be one of red, blue, green, and white.

The first pixel P1 may include a first pixel circuit PC1 and a first organic light-emitting diode OLED1 as a display element electrically connected to the first pixel circuit PC1. The second pixel P2 may include a second pixel circuit PC2 and a second organic light-emitting diode OLED2 electrically connected to the second pixel circuit PC2. The third pixel P3 may include a third pixel circuit PC3 and a third organic light-emitting diode OLED3 electrically connected to the third pixel circuit PC3.

A buffer layer 201 for preventing impurities from infiltrating into a semiconductor layer Act of a thin film transistor TFT of the first pixel circuit PC1 may be disposed on the substrate 100. The buffer layer 201 may include an inorganic insulating material, such as SiNₓ, SiON, and SiOₓ, and may be a single layer or multilayer including the inorganic insulating material described above.

The first pixel circuit PC1, the second pixel circuit PC2, and the third pixel circuit PC3 may be disposed on the buffer layer 201. The first pixel circuit PC1 may include a thin film transistor TFT and a storage capacitor Cst. The thin film transistor TFT may include a semiconductor layer Act, a gate electrode GE, a source electrode SE, and a drain electrode DE. The thin film transistor TFT illustrated in FIG. 16 may correspond to a first thin film transistor described with reference to FIG. 15. The data line DL may be electrically connected to a second thin film transistor included in the first pixel circuit PC1, although not illustrated in FIG. 16. Although in the embodiment, a top gate type in which the gate electrode GE is disposed on the semiconductor layer Act with a gate insulating layer 203 between the gate electrode GE and the semiconductor layer Act is described, the disclosure is not limited thereto, and according to another embodiment, the thin film transistor TFT may be of a bottom gate type. The second pixel circuit PC2, the third pixel circuit PC3, and the first pixel circuit PC1 may have a same or similar structure. The respective constituent elements of the first pixel circuit PC1 are described.

The semiconductor layer Act may include polysilicon. In another embodiment, the semiconductor layer Act may include amorphous silicon, an oxide semiconductor, an organic semiconductor, or the like. The gate electrode GE may include a low-resistance metal material. The gate electrode GE may include a conductive material such as Mo, Al, Cu, Ti, and the like, and may be formed in a multilayer or single layer including the material described above.

The gate insulating layer 203 between the semiconductor layer Act and the gate electrode GE may include an inorganic insulating material, such as SiOₓ, SiNₓ, SiON, an aluminum oxide (Al₂O₃), a titanium oxide (TiOₓ), a tantalum oxide (Ta₂O₅), a hafnium oxide (HfO₂), and the like. The gate insulating layer 203 may be a single layer or multilayer including the material described above.

The storage capacitor Cst may include a lower electrode CE1 and an upper electrode CE2 overlapping each other in a plan view with a first interlayer insulating layer 205 between the lower electrode CE1 and the upper electrode CE2. The storage capacitor Cst may overlap the thin film transistor TFT in a plan view. FIG. 16 illustrates that the gate electrode GE of the thin film transistor TFT is the lower electrode CE1 of the storage capacitor Cst, but the disclosure is not limited thereto. In another embodiment, the storage capacitor Cst may not overlap the thin film transistor TFT in a plan view. The storage capacitor Cst may be covered by a second interlayer insulating layer 207. The upper electrode CE2 of the storage capacitor Cst may include a conductive material such as Mo, Al, Cu, Ti, and the like, and may be formed in a multilayer or single layer including the material described above.

The first interlayer insulating layer 205 and the second interlayer insulating layer 207 may each include an inorganic insulating material, such as SiOₓ, SiNₓ, SiON, Al₂O₃, TiOₓ, Ta₂O₅, HfO₂, and the like. The first interlayer insulating layer 205 and the second interlayer insulating layer 207 may each be a single layer or multilayer including the material described above.

The source electrode SE, the drain electrode DE, and the data line DL may be located on a same layer, and may include a same material. For example, the source electrode SE, the drain electrode DE, and the data line DL may be located on the second interlayer insulating layer 207. The source electrode SE, the drain electrode DE, and the data line DL may include a material having superior conductivity. The source electrode SE and the drain electrode DE may each include a conductive material such as Mo, Al, Cu, Ti, and the like, and may be formed in a multilayer or single layer including the material described above. In an embodiment, the source electrode SE, the drain electrode DE, and the data line DL may be formed in a multilayer of Ti/AI/Ti.

The first pixel circuit PC1, the second pixel circuit PC2, and the third pixel circuit PC3, each including the thin film transistor TFT and the storage capacitor Cst, may be covered by a first organic insulating layer 209. The first organic insulating layer 209 may include an upper surface that has approximately a flat surface.

The first organic light-emitting diode OLED1 electrically connected to the first pixel circuit PC1, the second organic light-emitting diode OLED2 electrically connected to the second pixel circuit PC2, and the third organic light-emitting diode OLED3 electrically connected to the third pixel circuit PC3 may be located above the first organic insulating layer 209.

The first pixel circuit PC1 may be electrically connected to a first pixel electrode 221r of the first organic light-emitting diode OLED1. For example, as illustrated in FIG. 16, a contact metal layer CM may be provided between the thin film transistor TFT and the first pixel electrode 221r. The contact metal layer CM may be connected to the thin film transistor TFT through a contact hole penetrating the first organic insulating layer 209. The first pixel electrode 221r may be connected to the contact metal layer CM through a contact hole penetrating a second organic insulating layer 211 on the contact metal layer CM. The contact metal layer CM may include a conductive material such as Mo, Al, Cu, Ti, and the like, and may be formed in a multilayer or single layer including the material described above. In an embodiment, the contact metal layer CM may be formed in a multilayer of Ti/AI/Ti.

The first organic insulating layer 209 and the second organic insulating layer 211 may each include a general purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or blends thereof. In an embodiment, the first organic insulating layer 209 and the second organic insulating layer 211 may include polyimide.

According to another embodiment, one of the first organic insulating layer 209 and the second organic insulating layer 211 may be omitted, and the contact metal layer CM may be omitted.

The first organic light-emitting diode OLED1 may include the first pixel electrode 221r, a first emission layer 222r, and a first counter electrode 223r. The second organic light-emitting diode OLED2 may include a second pixel electrode 221g, a second emission layer 222g, and a second counter electrode 223g. The third organic light-emitting diode OLED3 may include a third pixel electrode 221b, a third emission layer 222b, and a third counter electrode 223b. The second organic light-emitting diode OLED2, the third organic light-emitting diode OLED3, and first organic light-emitting diode OLED1 may have a same or similar structure.

The first pixel electrode 221r may be disposed on the second organic insulating layer 211. The first pixel electrode 221r may include a conductive oxide, such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the first pixel electrode 221r may include a reflective film including silver (Ag), magnesium (Mg), Al, platinum (Pt), palladium (Pd), gold (Au), nickel (Ni), neodymium (Nd), iridium (Ir), chromium (Cr), or a compound thereof. In another embodiment, the first pixel electrode 221r may further include a film formed of ITO, IZO, ZnO, or In₂O₃ above/below the reflective film described above.

A pixel defining layer 213 and a bank layer 215 may be disposed on the first pixel electrode 221r. The pixel defining layer 213 may overlap an edge of the first pixel electrode 221r in a direction (the z axis direction) approximately perpendicular to the substrate 100. The pixel defining layer 213 may include an inorganic insulating material, such as SiNₓ, SiON, or SiOₓ.

A first remaining sacrificial layer 212R may be located between the first pixel electrode 221r and the pixel defining layer 213. The first remaining sacrificial layer 212R may be a portion left after a sacrificial layer for protecting an upper surface of the first pixel electrode 221r is removed. The first remaining sacrificial layer 212R may be located in an area where the pixel defining layer 213 and the first pixel electrode 221r overlap each other, in a direction (the z axis direction) approximately perpendicular to the substrate 100. For example, the first remaining sacrificial layer 212R may be located along the edge of the first pixel electrode 221r to expose the central portion of the first pixel electrode 221r.

The first remaining sacrificial layer 212R may be continuously formed with the first pixel electrode 221r, and may include a selectively etchable material without damage to the first pixel electrode 221r. For example, the first remaining sacrificial layer 212R may include an indium gallium zinc oxide (IGZO) and/or an indium zinc oxide (IZO).

The first remaining sacrificial layer 212R and the pixel defining layer 213 that overlap the edge of the first pixel electrode 221r may increase a distance between the first pixel electrode 221r and the first counter electrode 223r and between the bank layer 215 and the first counter electrode 223r, thereby preventing generation of an arc and the like therebetween. In embodiments, as the sacrificial layer is completely removed, the first remaining sacrificial layer 212R may not be present. A recess generated as the sacrificial layer between the first pixel electrode 221r and the pixel defining layer 213 is removed may be empty, or filled with the first emission layer 222r described below.

The bank layer 215 may be disposed on the pixel defining layer 213. The bank layer 215 may include a conductive material. For example, the bank layer 215 may include a conductive material such as Mo, Al, Cu, Ti, and the like, and may be formed in a multilayer or single layer including the material described above. For example, the bank layer 215 may have a structure of a double layer of Al/Ti or a triple layer of Ti/AI/Ti.

The pixel defining layer 213 and the bank layer 215 may extend from the display area DA of the substrate 100 to the peripheral area PA (see FIG. 14), and the bank layer 215 may directly contact the common power supply wire 16 (see FIG. 14) located in the peripheral area PA (see FIG. 14) through an opening portion of the pixel defining layer 213. Accordingly, the bank layer 215 may function as a connection electrode or auxiliary wire for transmitting the common voltage ELVSS to the first counter electrode 223r, the second counter electrode 223g, and the third counter electrode 223b described below.

A first conductive layer 217 may be disposed on the bank layer 215. The first conductive layer 217 may have a tip 217T protruding outward with respect to the center of the first pixel electrode 221r. In a plan view (in a direction (the z axis direction) perpendicular to the upper surface of the substrate 100), the tip 217T of the first conductive layer 217 may have a loop shape completely surrounding the first pixel electrode 221r.

A first opening OP1 may expose the upper surface of the central portion of the first pixel electrode 221r through the pixel defining layer 213, the bank layer 215, and the first conductive layer 217, and the first emission layer 222r described below may overlap and contact the first pixel electrode 221r through the first opening OP1. Accordingly, the first opening OP1 may define a first emission area EA1. The outside of the first emission area EA1 may be defined as a non-emission area NEA. Likewise, a second opening OP2 may define a second emission area EA2, and a third opening OP3 may define a third emission area EA3.

A part of the first conductive layer 217 may form the tip 217T that is apart from the bank layer 215 in the direction (the z axis direction) perpendicular to the substrate 100 and protrudes outward with respect to the center of the first pixel electrode 221r. As the tip 217T of the first conductive layer 217 is formed as a part of the sacrificial layer provided between the first conductive layer 217 and the bank layer 215 is removed, the first conductive layer 217 may have an undercut structure. Accordingly, the tip 217T of the first conductive layer 217 may form an eaves structure in which a lower surface thereof is exposed. A protrusion length of the tip 217T of the first conductive layer 217 may be greater than or equal to about 0.5 μm. In embodiments, the protrusion length of the tip 217T of the first conductive layer 217 may be in a range of about 0.3 μm to about 1 μm. In embodiments, the protrusion length of the tip 217T of the first conductive layer 217 may be in a range of about 0.3 μm to about 0.7 μm.

The first conductive layer 217 may include a conductive material. For example, the first conductive layer 217 may include a conductive material such as Mo, Al, Cu, Ti, and the like, and may be formed in a multilayer or single layer including the material described above. For example, the first conductive layer 217 may have a structure of a double layer of Al/Ti or a triple layer of Ti/AI/Ti.

In an embodiment, a low reflective layer (not shown) may be disposed on the first conductive layer 217. The low reflective layer may be a layer having a surface reflectivity less than a surface reflectivity of the first conductive layer 217. The low reflective layer may prevent light (external light) input toward the display device 2 from being reflected by a surface of the first conductive layer 217 and perceived by a user of the display device 2.

In an embodiment, the low reflective layer may include a low reflection material. The low reflection material may include a metal oxide having a high light absorbance, for example, a high extinction coefficient k. For example, the low reflective layer may include at least one of a copper oxide (CuO), a calcium oxide (CaO), a molybdenum oxide (MoOₓ), and a zinc oxide (ZnO). In embodiments, the low reflective layer may include a material in which CuO and CaO are mixed.

A second remaining sacrificial layer 214R may be provided between the first conductive layer 217 and the first conductive layer 217. The second remaining sacrificial layer 214R may be a remaining portion of the sacrificial layer that is removed to form the tip 217T of the first conductive layer 217. The second remaining sacrificial layer 214R may be spaced apart from the first pixel electrode 221r by a distance in a plan view (in a direction (the z axis direction) approximately perpendicular to the substrate 100), and may have a loop shape completely surrounding the first pixel electrode 221r. The first conductive layer 217 may have an undercut structure due to the second remaining sacrificial layer 214R.

The second remaining sacrificial layer 214R may determine the protrusion length of the tip 217T of the first conductive layer 217. For example, the second remaining sacrificial layer 214R may be located inside from an end of the tip 217T of the first conductive layer 217, and the protrusion length of the tip 217T may be a length from a sidewall of the second remaining sacrificial layer 214R to the end of the tip 217T.

The second remaining sacrificial layer 214R may include a selectively etchable material without damage to the first pixel electrode 221r, the bank layer 215, and the first conductive layer 217. For example, the second remaining sacrificial layer 214R and the first remaining sacrificial layer 212R may include a same material. The second remaining sacrificial layer 214R may include IGZO and/or IZO.

The first emission layer 222r may be arranged over the first pixel electrode 221r and the first conductive layer 217. For example, the first emission layer 222r may be arranged to contact the first pixel electrode 221r through the first opening OP1. The first pixel electrode 221r may include a polymer or low molecular weight organic material that emits light of a first color (e.g., red). In another embodiment, the first emission layer 222r may include an inorganic material or quantum dots.

The first emission layer 222r may include a first function layer (not shown) and a second function layer (not shown) above and/or under the first functional layer. The first function layer may include a hole transport layer (HTL) and/or a hole injection layer (HIL). The second function layer may include an electron transport layer (ETL) and/or an electron injection layer (EIL).

Although FIG. 16 illustrates a single stack structure including a single emission layer, the disclosure is not limited thereto, and in another embodiment, the display device 2 may have a tandem structure that is a multi-stack structure including multiple emission layers. In the tandem structure, a charge generation layer CGL may be arranged between multiple stacks.

The first emission layer 222r may be separated from a dummy portion 222rp by the tip 217T of the first conductive layer 217. The first emission layer 222r and the dummy portion 222rp may include sublayers (e.g., the first function layer, the second function layer, and the like) having a same material and/or the same number.

The first emission layer 222r may have at least one first hole 222rh that exposes a part of an upper surface of the first conductive layer 217.

The second emission layer 222g may include a polymer or low molecular weight organic material that emits light of a second color (e.g., green), and the third emission layer 222b may include a polymer or low molecular weight organic material that emits light of a third color (e.g., blue).

The first counter electrode 223r may be separated from a dummy portion 223rp by the tips 217T of the first conductive layer 217. The first counter electrode 223r and the dummy portion 223rp may include a same material.

The first counter electrode 223r may include a (semi-)transparent layer including Ag, Mg, Al, Pt, Pd, Au, Ni, Nd, Ir, Cr, lithium (Li), calcium (Ca), an alloy thereof, or the like. In an embodiment, the first counter electrode 223r may further include a layer including ITO, IZO, ZnO, or In₂O₃ on the (semi-)transparent layer including the material described above.

A first inorganic encapsulation layer 311 may be disposed on the first counter electrode 223r. As the first inorganic encapsulation layer 311 has a relatively excellent step coverage, the first inorganic encapsulation layer 311 may cover at least a part of an exposed lower surface of the tip 217T of the first conductive layer 217. For example, the first inorganic encapsulation layer 311 may be continuously formed to cover the upper surface and side surface of the first counter electrode 223r, the side surface of the first emission layer 222r, the side surface and lower surface of the tip 217T of the first conductive layer 217, the side surface of the second remaining sacrificial layer 214R, and the upper surface of the bank layer 215.

The first inorganic encapsulation layer 311 may include an inorganic insulating material such as SiNₓ, SiON, and SiOₓ. The first inorganic encapsulation layer 311 may directly contact a metal surface in the side surface and lower surface of the tip 217T of the first conductive layer 217, thereby forming an inorganic contact region ICR. Accordingly, the inorganic contact region ICR may form a closed loop that completely surrounds the first organic light-emitting diode OLED1, thereby reducing or preventing a path along which impurities such as moisture and/or air infiltrates.

As illustrated in FIG. 16, a second inorganic encapsulation layer 312 may seal the second organic light-emitting diode OLED2, and a third inorganic encapsulation layer 313 may seal the third organic light-emitting diode OLED3. As the first inorganic encapsulation layer 311, the second inorganic encapsulation layer 312, and the third inorganic encapsulation layer 313 form the inorganic contact region ICR in the display area DA, an inorganic contact region in the peripheral area PA (see FIG. 14), which is necessary for reducing a delamination defect by the emission layer, may be reduced. Furthermore, as an organic light-emitting diode is sealed in units of pixels, even in case that a path along which impurities such as moisture and/or air infiltrates occurs at a boundary of one pixel or the substrate 100, a defect may be prevented from being transferred to neighboring pixels.

An organic planarization layer 410 may be arranged to cover the first inorganic encapsulation layer 311, the second inorganic encapsulation layer 312, and the third inorganic encapsulation layer 313. The organic planarization layer 410 may cover unevenness by the pixel defining layer 213, the bank layer 215, and the first conductive layer 217, thereby providing a flat base surface to constituent elements arranged above the organic planarization layer 410. The organic planarization layer 410 may include a polymer-based material. For example, the organic planarization layer may include an acrylic resin, an epoxy-based resin, polyimide, polyethylene, or the like.

In an embodiment, the refractive index of the organic planarization layer 410 may be greater than refractive indexes of the first inorganic encapsulation layer 311, the second inorganic encapsulation layer 312, and the third inorganic encapsulation layer 313. For example, the refractive index of the organic planarization layer 410 may be greater than or equal to about 1.6. The refractive index of the organic planarization layer 410 may be in a range of about 1.6 to about 1.9. The organic planarization layer 410 may further include dispersion particles for high refraction. For example, metal oxide particles, such as a zinc oxide (ZnOₓ), a titanium oxide (TiO₂), a zirconium oxide (ZrO₂), barium titanate (BaTiO₃), and the like may be dispersed in the organic planarization layer 410.

A protective layer 420 may be disposed on the organic planarization layer 410. The protective layer 420 may include an inorganic insulating material, such as SiNₓ, SiON, and SiOₓ. In an embodiment, the refractive index of the protective layer 420 may be less than the refractive index of the organic planarization layer 410.

An antireflective layer 500 including a first color filter 510, a second color filter 520, a third color filter 530, a light shielding layer 540, and an overcoat layer 550 may be disposed on the protective layer 420. The antireflective layer 500 may reduce the reflectivity of light (external light) incident on the display device 2 from the outside.

The light shielding layer 540 may overlap the bank layer 215 and the first conductive layer 217 in a plan view, and thus, at least partially absorb the reflected light by the bank layer 215 and the first conductive layer 217 in the non-emission area NEA. The non-emission area NEA may be an area that does not overlap the first emission area EA1, the second emission area EA2, and the third emission area EA3. The light shielding layer 540 may include a black pigment. The light shielding layer 540 may be a black matrix. The light shielding layer 540 may have a first filter opening 540OP1 corresponding to the first emission area EA1, a second filter opening 540OP2 corresponding to the second emission area EA2, and a third filter opening 540OP3 corresponding to the third emission area EA3.

The first color filter 510 may be located within the first filter opening 540OP1 to correspond to the first emission layer 222r arranged under the first color filter 510. The first color filter 510 may selectively transmit the light emitted from the first emission layer 222r. For example, the first color filter 510 illustrated in FIG. 16 may be a red color filter that transmits red light.

Likewise, the second color filter 520 may be located within the second filter opening 540OP2 to correspond to the second emission layer 222g. The second color filter 520 may selectively transmit the light emitted from the second emission layer 222g. The third color filter 530 may be located within the third filter opening 540OP3 to correspond to the third emission layer 222b. The third color filter 530 may selectively transmit the light emitted from the third emission layer 222b. For example, the second color filter 520 illustrated in FIG. 16 may be a green color filter that transmits green light, and the third color filter 530 may be a blue color filter that transmits blue light.

The overcoat layer 550 may be disposed on the first to third color filters 510, 520, and 530. The overcoat layer 550, as a light-transmissive layer, may cover unevenness by the first to third color filters 510, 520, and 530 and the light shielding layer 540, thereby providing a flat upper surface. The overcoat layer 550 may include a colorless light-transmissive organic material, such as an acryl-based resin.

According to embodiments, in the apparatus for manufacturing a display device, manufacturing speed and manufacturing quality may be improved.

The effects of the disclosure are not limited to the above-described effects, and other various effects that are not described in the specification may be clearly understood from the following descriptions by one skilled in the art to which the disclosure belongs.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a display device, the apparatus comprising:
a chamber;
a mask assembly arranged in the chamber and facing a display substrate;
a magnetic force portion arranged in the chamber and applying a magnetic force to the mask assembly; and
a deposition source arranged in the chamber, facing the mask assembly, and supplying a deposition material to deposit on the display substrate by passing through the mask assembly, wherein
the mask assembly comprises:
a first mask layer having a first mask opening formed therein; and
a second mask layer disposed on the first mask layer,
the second mask layer comprises:
a metal layer having a metal opening formed therein; and
an inorganic layer disposed on the metal layer and having an inorganic opening overlapping the first mask opening in a plan view, and
the metal opening overlaps the inorganic opening in a plan view.

2. The apparatus of claim 1, wherein, in a plan view, the metal layer surrounds the inorganic opening.

3. The apparatus of claim 1, wherein at least a part of the inorganic layer is arranged within the metal opening.

4. The apparatus of claim 1, wherein the metal layer comprises a plurality of metal layers.

5. The apparatus of claim 4, wherein, in a plan view, the plurality of metal layers are spaced apart from each other by a distance.

6. The apparatus of claim 4, wherein, in a cross-sectional view, at least a part of the inorganic layer is arranged between the plurality of metal layers.

7. The apparatus of claim 1, wherein a lower surface of the metal layer is exposed from the inorganic layer.

8. The apparatus of claim 1, wherein the inorganic layer covers an upper surface of the metal layer.

9. A method of manufacturing a display device, the method comprising:
arranging a display substrate in a chamber;
arranging a mask assembly in the chamber;
applying, by a magnetic force portion, a magnetic force to the mask assembly; and
supplying, by a deposition source, a deposition material toward the mask assembly,
wherein the arranging of the mask assembly comprises:
disposing a metal layer on a first mask layer;
forming a metal opening in the metal layer;
disposing an inorganic layer on the metal layer;
forming a first mask opening in the first mask layer; and
forming an inorganic opening in the inorganic layer overlapping the metal opening in a plan view.

10. The method of claim 9, wherein the forming of the inorganic opening in the inorganic layer comprises etching the inorganic layer in a direction in which the first mask layer faces the metal layer.

11. The method of claim 10, wherein a lower portion of the metal layer is exposed from the inorganic layer, according to the etching of the inorganic layer.

12. The method of claim 9, wherein the metal layer surrounds the inorganic opening, according to the forming of an inorganic opening in the inorganic layer.

13. The method of claim 9, wherein at least a part of the inorganic layer is arranged within the metal opening, according to the arranging of the inorganic layer.

14. The method of claim 9, wherein the metal layer comprises a plurality of metal layers.

15. The method of claim 14, wherein, in a plan view, the plurality of metal layers are spaced apart from each other by a distance.

16. The method of claim 14, wherein, in a cross-sectional view, at least a part of the inorganic layer is arranged between the plurality of metal layers.

17. The method of claim 9, wherein the inorganic layer covers an upper surface of the metal layer, according to the arranging of the inorganic layer.
